(19) United States
(12) Patent Application Publication
(10) Pub. No.: US 2002/0067834 A1
(43) Pub. Date: Jun. 6, 2002

(54) Encoding and decoding system for audio signals

(76) Inventor: Toru Shirayanagi, Hamamatsu-shi (JP)

Correspondence Address: Pillsbury Winthrop LLP, Intellectual Property Group, Suite 2800, 725 South Figueroa Street, Los Angeles, CA, 90017-5406, US

(21) Appl. No.: 10/007,422

(22) Filed: Dec. 5, 2001

(30) Foreign Application Priority Data
Dec. 6, 2000 (JP) P2000-371458

(51) Int. Cl. H03G 7/00; H04R 5/00

(52) U.S. Cl. 381/20; 381/106

(57) ABSTRACT

An encoding device converts four-channel or five-channel audio signals to two-channel audio signals, which are then subjected to compression in accordance with the MPEG standard. Matrix coefficients are calculated based on the two-channel audio signals. A decoding device receives the compressed two-channel audio signals together with the matrix coefficient. The compressed two-channel audio signals are expanded and are then subjected to prescribed arithmetic operations using the matrix coefficients. Thus, the decoding device reproduces the original audio signals. The decoding device, which is normally actualized by a digital signal processor (DSP), is noticeably reduced in amounts of calculations and is simplified in circuit configuration because of the elimination of calculations of matrix coefficients therein.

### BACKGROUND OF THE INVENTION

1. Field of the Invention

This invention relates to encoding and decoding systems for audio signals, and particularly to encoding devices for encoding and compressing audio signals and decoding devices for decoding and expanding audio signals for use in broadcasting stations, digital contents providers, and manufacturers as well as home electronics such as digital versatile disk (DVD) drives and players.

2. Description of the Related Art

Recently, a variety of digital storage media for storing digital contents have been produced and distributed by digital contents providers and manufacturers. Particularly, digital versatile disks (DVDs) are widely used to record audio and video contents such as broadcast programs and movies. The DVDs normally record four-channel or five-channel audio signals, which are reproduced by DVD drives or players. FIG. 2 diagrammatically shows a system handling five-channel audio signals that provides an encoding device (or a compression device) 1 and a decoding device (or an expansion device) 2. The encoding device 1 is used in the DVD provider or manufacturer while the decoding device 2 is installed in a DVD drive or player, which is located at home, for example.

The encoding device 1 provides five channels denoted by reference symbols L, C, R, LS, and RS, which represent digital audio signals (namely, pulse-code-modulated signals or ‘PCM’ signals). That is, various microphones are used to pick up sounds and produce analog audio signals, which are subjected to analog-to-digital conversion to produce digital audio signals. The microphones are located at different positions to provide five-channel digital audio signals, as follows:

L . . . Left microphone.

C . . . Center microphone.

R . . . Right microphone.

LS . . . Left-rear microphone.

RS . . . Right-rear microphone.

The encoding device 1 contains a matrix encoder 3 that performs encoding on five-channel digital audio signals L, C, R, LS, and RS, which are converted to two-channel digital audio signals Lt and Rt. A compression circuit 4 inputs two-channel digital audio signals Lt and Rt, and it performs decoding (namely, data compression) based on a prescribed standard such as the MPEG standard (where ‘MPEG’ is an abbreviation for ‘Moving Picture Expert Group’). Thus, the compression circuit 4 provides compressed digital audio signals in the form of bit streams, which are recorded on various types of digital storage media such as DVDs. Broadcasting stations are capable of broadcasting digital contents based on compressed digital audio signals and corresponding video signals.

The decoding device 2 receives the compressed digital audio signals, or it reads them from a digital storage medium (e.g., DVD). In the decoding device 2, an expansion circuit 7 reproduces the digital audio signals Lt and Rt by performing expansion on the compressed digital audio signals in accordance with the prescribed procedures of the MPEG standard, for example. The digital audio signals Lt and Rt output from the expansion circuit 7 are supplied to a matrix decoder 8, which reproduces the ‘original’ five-channel digital audio signals. The matrix decoder 8 is composed of a matrix coefficient calculation circuit 9 and five calculation circuits 10 to 14, which are provided in correspondence with the five channels respectively. The matrix coefficient calculation circuit 9 produces matrix coefficients ‘mat-a’ to ‘mat-j’ by performing calculations based on the reproduced digital audio signals Lt and Rt. The calculation circuits 10 to 14 perform arithmetic operations on the signals Lt and Rt in accordance with the matrix coefficients mat-a to mat-j, thus reproducing the digital audio signals L, C, R, LS, and RS respectively. Specifically, the calculation circuit 10 performs the following arithmetic operations using the matrix coefficients mat-a and mat-b for reproduction of the digital audio signal L.

L=Lt×mat-a+Rt×mat-b

Similarly, the other calculation circuits 11-14 perform prescribed arithmetic operations using the other matrix coefficients mat-c to mat-j for reproduction of the digital audio signals C, R, LS, and RS.

Normally, the decoding device 2 is composed of a digital signal processor (i.e., DSP). Herein, the matrix coefficient calculation circuit 9 performs complicated calculations that require a great calculating ability in the performance of the DSP, that is, 10 MIPS (i.e., ten million instructions per second), for example. For this reason, a large part of the processing ability of the DSP should be occupied by the complicated calculations of the matrix coefficient calculation circuit 9. This raises the problem that the DSP may not be used for processing of other operations during execution of the complicated calculations of the matrix coefficient calculation circuit 9.

### SUMMARY OF THE INVENTION

It is an object of the invention to provide an encoding and decoding system that is composed of an encoding device for encoding and compressing audio signals and a decoding device for expanding compressed audio signals, wherein the amount of calculations performed in the decoding device is remarkably reduced to ease processing loads to a digital signal processor (DSP).

The encoding and decoding system of this invention is basically composed of an encoding device for encoding and compressing audio signals and a decoding device for decoding and expanding audio signals, wherein the encoding device is provided in a broadcasting station or a digital contents manufacturer, whereas the decoding device, which is actualized by a digital signal processor (DSP), is installed in a home appliance such as a DVD drive or player.

The encoding device inputs four-channel or five-channel audio signals, which are suited to recording of digital signals on digital storage media such as DVDs. That is, the encoding device converts the four-channel or five-channel audio signals to two-channel audio signals, which are then subjected to compression in accordance with the MPEG standard, for example. Matrix coefficients are calculated based on the two-channel audio signals. The compressed two-channel audio signals together with the matrix coefficients are recorded on the prescribed digital storage medium such as a DVD, which is manufactured by the digital contents manufacturer or which is distributed by the digital contents provider. Alternatively, the broadcasting station is capable of broadcasting digital contents based on the compressed two-channel audio signals together with the matrix coefficients. This eliminates the necessity of performing complicated calculations for producing the matrix coefficients in the decoding device, so that its circuit configuration can be simplified, and its processing load can be reduced.

The decoding device inputs the compressed two-channel audio signals together with the matrix coefficient. The compressed two-channel audio signals are expanded and are then subjected to prescribed arithmetic operations using the matrix coefficients. Thus, the decoding device reproduces the original audio signals.

### BRIEF DESCRIPTION OF THE DRAWINGS

These and other objects, aspects, and embodiments of the present invention will be described in more detail with reference to the following drawing figures, in which:

FIG. 1 is a block diagram diagrammatically showing an encoding and decoding system that is composed of an encoding device including calculations of matrix coefficients and a decoding device having processing load that is reduced in accordance with the preferred embodiment of the invention; and

FIG. 2 is a block diagram diagrammatically showing an encoding and decoding system that is composed of an encoding device and a decoding device containing a matrix decoder bearing processing loads for calculations of matrix coefficients.

### DESCRIPTION OF THE PREFERRED EMBODIMENT

This invention will be described in further detail by way of examples with reference to the accompanying drawings.

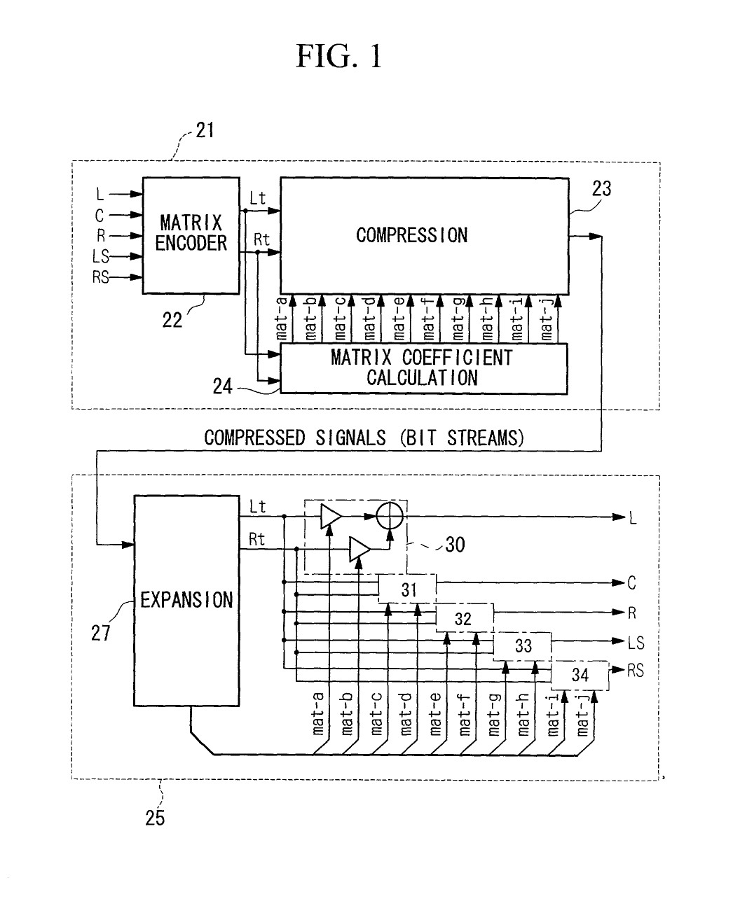

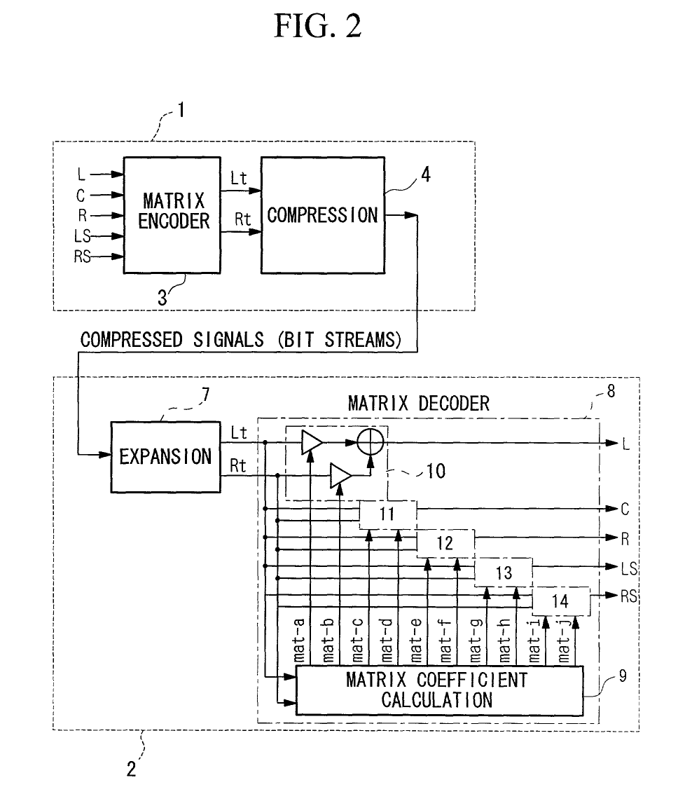

FIG. 1 diagrammatically shows a system that is composed of an encoding device (or a compression device) 21 and a decoding device (or an expansion device) 25. The encoding device 21 provides a matrix encoder 22 that inputs five-channel digital audio signals L, C, R, LS, and RS. The matrix encoder 22 performs encoding on the five-channel digital signals in accordance with the Circle Surround standard, thus producing two-channel digital audio signals Lt and Rt. These signals are delivered to a compression circuit 23 and a matrix coefficient calculation circuit 24 respectively. The matrix coefficient calculation circuit 24 performs prescribed calculations on the two-channel digital audio signals Lt and Rt to produce matrix coefficients ‘mat-a’ to ‘mat-j’, which are supplied to the compression circuit 23. The matrix coefficient calculation circuit 24 has roughly the same circuit configuration of the foregoing matrix coefficient calculation circuit 9 that is used in the decoding device 2 shown in FIG. 2.

The compression circuit 23 performs compression on the two-channel digital audio signals Lt and Rt in accordance with the aforementioned MPEG standard or the DTS (i.e., Digital Theater Sound) standard, for example. That is, the compression circuit 23 produces compressed signals (or bit streams), which accompany the matrix coefficients mat-a to mat-j and are output from the encoding device 21. Hence, the compressed digital audio signals are output from the encoding device 21 and are then recorded on various types of digital storage media such as DVDs. Broadcasting stations are capable of broadcasting digital contents based on compressed digital audio signals and corresponding video signals.

The decoding device 25 receives the compressed digital audio signals, or it reads audio and video data from the digital storage media such as DVDs. In the decoding device 25, an expansion circuit 27 extracts the compressed digital audio signals from the input data thereof. In accordance with the procedures of the prescribed standard that is used for the compression in the encoding device 21, the expansion circuit 27 performs expansion on the compressed digital audio signals to reproduce the two-channel digital audio signals Lt and Rt, which are delivered to calculation circuits 30 to 34 respectively. In addition, the expansion circuit 27 also extracts from the input data thereof the matrix coefficients mat-a to mat-j, which are delivered to the calculation circuits 30 to 34 respectively. The calculation circuits 30 to 34 have roughly the same circuit configurations as the foregoing calculation circuits 10 to 14 that are used in the decoding device 2 shown in FIG. 2. Herein, each of the calculation circuits 30 to 34 is composed of two multipliers and one adder, for example. In the calculation circuit 30, for instance, the two-channel digital audio signals Lt and Rt are respectively multiplied by the matrix coefficients mat-a and mat-b, so that the multiplication results are added together to reproduce the digital audio signal L. In short, the calculation circuits 30 to 34 perform prescribed calculations using the matrix coefficients mat-a to mat-j, thus reproducing the ‘original’ five-channel digital audio signals L, C, R, LS, and RS respectively.

The aforementioned embodiment is designed in such a way that the five-channel digital audio signals L, C, R, LS, and RS are subjected to encoding to produce the two-channel digital audio signals Lt and Rt. Of course, this invention is not necessarily limited to the aforementioned embodiment. That is, this invention is applicable to the other ‘known’ encoding-decoding systems such as the encode-decode system of “Dolby Prologic” (registered trademark). The Dolby Prologic provides the standard for general households in which encoding and decoding processes are performed for the purpose of the mutual interchange between four-channel signals and two-channel signals in video/audio recording and reproduction. Specifically, four-channel signals L, R, C, and S are subjected to encoding to produce two-channel signals, which are recorded on the prescribed recording medium by the video recorder/player and the like; thereafter, the two-channel signals are read from the recording medium and are subjected to decoding to reproduce the four-channel signals. This standard employs the general encode-decode system of the matrix system, which may require a matrix decoder containing a matrix coefficient calculation circuit for a home appliance. This invention eliminates the necessity of providing the matrix coefficient calculation circuit inside of the matrix decoder, which may be composed of a digital signal processor (DSP). Hence, it is possible to noticeably reduce the processing load of the DSP that performs decoding processes.

The other ‘known’ standard such as the Dolby Digital standard originally deals with six-channel signals, which are subjected to compression in a discrete manner. This standard can be easily modified to handle two-channel signals. Therefore, the compression circuit 23 can be modified to perform compression on the two-channel digital audio signals Lt and Rt in a discrete manner in accordance with the Dolby Digital standard. That is, the encoding device 21 can employ various types of formats for signal compression methods, which are generally known and usable in compressions of two-channel signals, for example.

As described heretofore, this invention has a variety of technical features and effects, which will be described below,

(1) This invention basically provides an encoding and decoding system that is composed of an encoding device (or a compression device) and a decoding device (or an expansion device). The encoding device is characterized by providing therein calculations of matrix coefficients, which are used for decoding. That is, the encoding device outputs compressed digital audio signals together with the matrix coefficients. This eliminates the necessity of calculating the matrix coefficients in the decoding device. Therefore, it is possible to noticeably reduce the amount of calculations performed in the decoding device as compared with the conventional decoding device. Thus, it is possible to simplify the hardware and/or software configuration of the decoding device as compared with the conventional decoding device.

(2) The decoding device can be actualized by a digital signal processor (DSP) whose processing steps are remarkably reduced because of the elimination of calculations of matrix coefficients therein. This provides an extra space or room for execution of other processes in the DSP. In general, an encoding process (or compression) is performed by the broadcasting station or digital contents manufacturer once, whereas a decoding process (or expansion) is performed by the prescribed home appliance at each household. For this reason, the simplification of the decoding process (or expansion) provides a great significance for the practical use, rather than the simplification of the encoding process (or compression).

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. An encoding device for audio signals, comprising:
a matrix encoder for converting N-channel audio signals (where ‘N’ is an integer greater than zero) to M-channel audio signals (where ‘M’ is an integer smaller than ‘N’);
a matrix coefficient calculation unit for calculating matrix coefficients based on the M-channel audio signals, wherein the matrix coefficients are to be used in decoding of the M-channel audio signals; and
a compression unit for performing compression on the M-channel audio signals, thus producing compressed M-channel audio signals, which are output therefrom together with the matrix coefficients.

2. An encoding device according to claim 1, wherein the compression unit performs compression in accordance with the MPEG standard.

3. An encoding device according to claim 1, wherein M is set to four or five while N is set to two, so that the matrix encoder converts four-channel or five-channel audio signals to two-channel audio signals.

4. A decoding device for audio signals, comprising:
an expansion unit for receiving compressed M-channel signals (where ‘M’ is an integer greater than zero) together with matrix coefficients, so that the expander performs expansion on the compressed M-channel signals to reproduce M-channel signals; and
a calculation unit for performing prescribed calculations using the matrix coefficients on the M-channel audio signals, thus reproducing N-channel audio signals (where ‘N’ is an integer greater than ‘M’).

5. A decoding device according to claim 4, wherein the expansion unit performs expansion in accordance with MPEG standard.

6. A decoding device according to claim 4, wherein M is set to two while N is set to four or five, so that the calculation unit reproduces four-channel or five-channel audio signals based on two-channel audio signals.

7. A decoding device according to claim 4, wherein the calculation unit comprises N calculators, each of which performs arithmetic operations using corresponding matrix coefficients within the matrix coefficients so as to convert the M-channel audio signals to an audio signal of a single channel within N channels.

8. A decoding device according to claim 7, wherein each of the calculators comprises M multipliers performing multiplication using the corresponding matrix coefficients on the M-channel audio signals, and an adder for adding together multiplication results produced by the M multipliers respectively, so that the adder outputs the audio signal of the single channel.

9. A decoding device according to claim 4, wherein the calculation unit is actualized by a digital signal processor (DSP).

10. An encoding and decoding system for audio signals, comprising:
an encoding device in which N-channel audio signals (where ‘N’ is an integer greater than zero) are subjected to encoding to produce M-channel audio signals (where ‘M’ is an integer smaller than ‘N’), which are then subjected to compression to produce compressed M-channel audio signals in accordance with MPEG standard, wherein matrix coefficients are produced by performing prescribed calculations on the M-channel audio signals; and
a decoding device in which the compressed M-channel audio signals are subjected to expansion to reproduce the M-channel audio signals, which are then subjected to arithmetic operations using the matrix coefficients to reproduce the N-channel audio signals.

11. An encoding and decoding system according to claim 10, wherein the decoding device is actualized by a digital signal processor (DSP).
